(19) United States
(12) Patent Application Publication
(10) Pub. No.: US 2023/0125228 A1
(43) Pub. Date: Apr. 27, 2023

(54) RADIATION IMAGING APPARATUS, RADIATION IMAGING SYSTEM, METHOD OF CONTROLLING RADIATION IMAGING APPARATUS, AND STORAGE MEDIUM

(71) Applicant: CANON KABUSHIKI KAISHA, Tokyo (JP)

(72) Inventor: Katsuro Takenaka, Saitama (JP)

(21) Appl. No.: 18/048,362

(22) Filed: Oct. 20, 2022

(30) Foreign Application Priority Data
Oct. 26, 2021 (JP) 2021-174756

(51) Int. Cl. G01T 1/20; H01L 27/146

(52) U.S. Cl. CPC G01T 1/20184; H01L 27/14605; H01L 27/14609

(57) ABSTRACT

A plurality of conversion elements is arranged in a two-dimensional matrix and each configured to convert radiation into an electric signal. A plurality of switch elements is configured to turn on/off reading-out of a signal from a conversion element. A signal line extends in a column direction and is configured to be used for reading a signal from a conversion element. A drive line extends in a row direction and is connected to a switch element. A drive circuit is configured to supply a signal for turning-on/off a switch element. The drive line is shared between adjacent rows. The drive circuit switches a scanning direction between a case where signals from the plurality of conversion elements are read out individually and a case where signals from two or more conversion elements of the plurality of conversion elements are added and read out.

### BACKGROUND

### Technical Field

The present disclosure relates to a radiation imaging apparatus, a radiation imaging system, a method of controlling the radiation imaging apparatus, and a storage medium.

### Description of the Related Art

A radiation imaging apparatus is configured to electrically capture an optical image formed by radiation, and includes peripheral circuits disposed in a peripheral area of a pixel array. The peripheral circuits include a drive circuit for driving the pixel array and a readout circuit for reading out electric signal from the pixel array. Japanese Patent Laid-Open No. 2018-101909 discloses a radiation imaging apparatus configured to read out signals from conversion elements in two columns via one signal line by changing connections of conversion elements and switch elements. This simplifies the configuration of the readout circuit.

The radiation imaging apparatus has a capability of changing a resolution of a read-out image as required by switching a reading mode between a mode in which signals from conversion elements are read out on a pixel-by-pixel basis and a mode in which signals from conversion elements are collectively read out for a plurality of pixels (hereinafter, this mode will also be referred to as a pixel addition or the like). The pixel addition allows it to change not only the resolution of the read-out image but also a reading speed (a frame rate), an S/N ratio of an image, a data size, and/or the like, and thus the pixel addition is an essential capability for the radiation imaging apparatus.

However, when the radiation imaging apparatus disclosed in Japanese Patent Laid-Open No. 2018-101909 performs the pixel addition on pixels in 2 rows × 2 columns, a signal from a pixel other than the pixels in 2 rows × 2 columns is read out, and thus an accurate pixel addition is not achieved.

### SUMMARY

The present disclosure provides a technique of performing an accurate pixel addition while reducing the number of contacts between a pixel array and peripheral circuits. In an aspect, the present disclosure provides a radiation imaging apparatus including a plurality of conversion elements, a signal line, a plurality of switch elements, a plurality of drive lines, and a drive circuit. The plurality of conversion elements is arranged in a two-dimensional matrix and each configured to convert radiation into an electric signal. The plurality of conversion elements includes a first conversion element, a second conversion element adjacent in a row direction to the first conversion element, a third conversion element adjacent in a column direction to the first conversion element, a fourth conversion element adjacent in the column direction to the second conversion element and adjacent in the row direction to the third conversion element, a signal line for reading electric signals obtained by the plurality of conversion elements. The signal line is connected to the second conversion element and the fourth conversion element, to the first conversion element via the second conversion element, and to the third conversion element via the fourth conversion element. The plurality of switch elements includes a first switch element connected between the first conversion element and the second conversion element, a second switch element connected between the second conversion element and the signal line, a third switch element connected between the third conversion element and the fourth conversion element, a fourth switch element connected between the fourth conversion element and the signal line. The plurality of drive lines includes a first drive line connected to a control terminal of the first switch element, a second drive line connected to a control terminal of the second switch element and a control terminal of the third switch element, and a third drive line connected to a control terminal of the fourth switch element. The drive circuit is configured to supply, to each of the plurality of drive lines, an on-signal for turning on a switch element or an off-signal for turning off a switch element. The drive circuit reads out signals respectively from the first conversion element and the second conversion element by simultaneously supplying the on-signal to the first drive line and the second drive line, and then reads out signals respectively from the third conversion element and the fourth conversion element by simultaneously supplying the on-signal to the second drive line and the third drive line.

Further features of the disclosure will become apparent from the following description of exemplary embodiments with reference to the attached drawings.

### BRIEF DESCRIPTION OF THE DRAWINGS

FIG. 1 is a diagram illustrating an example of a configuration of a radiation imaging system according to a first embodiment.

FIG. 2 is a diagram illustrating an example of a configuration of a radiation imaging apparatus according to the first embodiment.

FIG. 3 is a diagram illustrating an example of a cross-sectional structure of a pixel according to the first embodiment.

FIG. 4 is a diagram illustrating an example of an operation of the radiation imaging system according to the first embodiment.

FIG. 5 is a diagram illustrating an example of a configuration of a drive circuit according to the first embodiment.

FIG. 6 is a diagram illustrating an example of an operation of the drive circuit according to the first embodiment.

FIG. 7 is a diagram illustrating an example of an operation of the radiation imaging system according to the first embodiment.

FIG. 8 is a diagram illustrating an example of a configuration of a radiation imaging apparatus according to a second embodiment.

FIG. 9 is a diagram illustrating an example of a configuration of a radiation imaging apparatus according to a third embodiment.

FIG. 10 is a diagram illustrating an example of an operation of the radiation imaging system according to the third embodiment.

FIG. 11 is a diagram illustrating an example of a configuration of a radiation imaging apparatus according to a fourth embodiment.

FIG. 12 is a diagram illustrating an example of an operation of the radiation imaging system according to the fourth embodiment.

FIG. 13 is a diagram illustrating an example of a configuration of a radiation imaging apparatus according to a fifth embodiment.

FIG. 14 is a diagram illustrating an example of an operation of the radiation imaging system according to the fifth embodiment.

### DESCRIPTION OF THE EMBODIMENTS

Embodiments are described in detail below with reference to the accompanying drawings. It should be noted that the following embodiments do not limit the scope of the present disclosure. Although a plurality of features are described in the embodiments, not all of these features are essential to the disclosure, and an arbitrary combination of these features is possible. In the accompanying drawings, same or similar parts are denoted by similar reference numerals, and a redundant description thereof is omitted. In the following, the term “unit” may refer to a software context, a hardware context, or a combination of software and hardware contexts. In the software context, the term “unit” refers to a functionality, an application, a software module, a function, a routine, a set of instructions, or a program that can be executed by a programmable processor such as a microprocessor, a central processing unit (CPU), or a specially designed programmable device or controller. A memory contains instructions or program that, when executed by the CPU, cause the CPU to perform operations corresponding to units or functions. In the hardware context, the term “unit” refers to a hardware element, a circuit, an assembly, a physical structure, a system, a module, or a subsystem. It may include mechanical, optical, or electrical components, or any combination of them. It may include active (e.g., transistors) or passive (e.g., capacitor) components. It may include semiconductor devices having a substrate and other layers of materials having various concentrations of conductivity. It may include a CPU or a programmable processor that can execute a program stored in a memory to perform specified functions. It may include logic elements (e.g., AND, OR) implemented by transistor circuits or any other switching circuits. In the combination of software and hardware contexts, the term “unit” or “circuit” refers to any combination of the software and hardware contexts as described above. In addition, the term “element,” “assembly,” “component,” or “device” may also refer to “circuit” with or without integration with packaging materials.

### First Embodiment

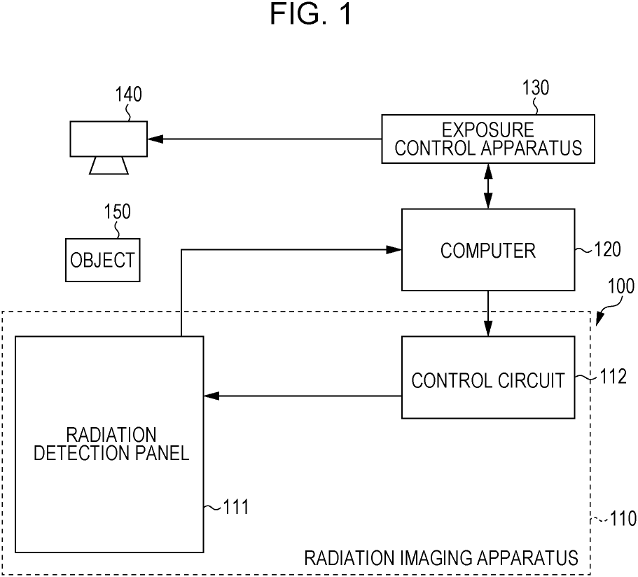

FIG. 1 shows an example of a configuration of a radiation imaging system 100 according to a first embodiment of the present disclosure. The radiation imaging system 100 is configured to electrically capture an optical image formed by radiation and obtain an electrical radiation image. Radiation is typically X-rays, but the radiation may be α-rays, β-rays, γ-rays, or the like. The radiation imaging system 100 includes, for example, a radiation imaging apparatus 110, a computer 120, an exposure control apparatus 130, and a radiation source 140.

The radiation source 140 is a device or circuit that starts irradiation of radiation according to an exposure command (radiation command) from the exposure control apparatus 130. The radiation emitted from the radiation source 140 passes through an object 150 and is incident on the radiation imaging apparatus 110. The radiation source 140 stops emitting the radiation according to a stop command from the exposure control apparatus 130.

The radiation imaging apparatus 110 includes a radiation detection panel 111 and a control circuit 112. The radiation detection panel 111 generates radiation image data according to the radiation incident on the radiation imaging apparatus 110 and transmits it to the computer 120. Here, the radiation image data refers to data representing the radiation image.

The control circuit 112 controls the operation of the radiation detection panel 111. For example, based on a signal supplied from the radiation detection panel 111, the control circuit 112 generates a stop signal for stopping the emission of the radiation from the radiation source 140. The stop signal is supplied to the exposure control apparatus 130. In response to the stop signal, the exposure control apparatus 130 sends the stop command to the radiation source 140.

The control circuit 112 is realized using, for example, a PLD (Programmable Logic Device) such as an FPGA (Field Programmable Gate Array). Alternatively, the control circuit 112 may be realized using a dedicated circuit such as an ASIC (Application Specific Integrated Circuit).

The control circuit 112 may be configured by a combination of a general-purpose processing circuit such as a processor and a storage circuit such as a memory. In this case, the function of the control circuit 112 may be realized by the general-purpose processing circuit by executing a program stored in the storage circuit.

The computer 120 includes a control unit configured to control the radiation imaging apparatus 110 and the exposure control apparatus 130, a reception unit or circuit configured to receive radiation image data from the radiation imaging apparatus 110, and a signal processing unit or circuit configured to process a signal (radiation image data) obtained by the radiation imaging apparatus 110.

The control unit, the reception unit, and the signal processing unit each may be configured by a dedicated circuit or by a combination of a general-purpose processing circuit and a memory circuit, as with the control circuit 112.

In one example, the exposure control apparatus 130 has an exposure switch. When the exposure switch is turned on by a user, the exposure control apparatus 130 sends an exposure command to the radiation source 140 and sends a radiation start notification to the computer 120. Upon receiving the radiation start signal, the computer 120 notifies the control circuit 112 of the radiation imaging apparatus 110 that the radiation has been started.

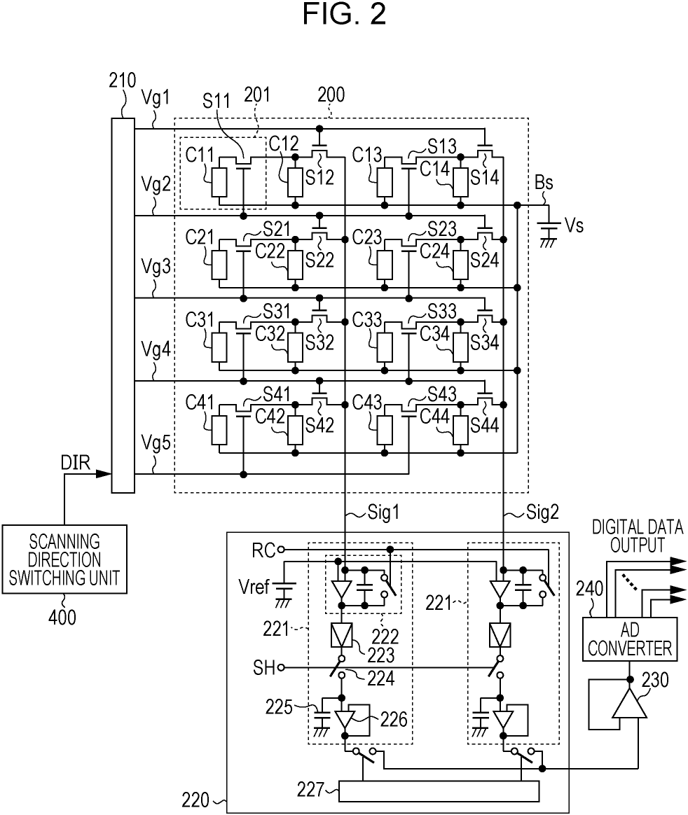

FIG. 2 shows an example of a configuration of the radiation detection panel 111. The radiation detection panel 111 includes, for example, a pixel array 200, a drive circuit 210, a readout circuit 220, a buffer circuit 230, an AD converter 240, and a scanning direction switching unit 400. The drive circuit 210 and the readout circuit 220 function as peripheral circuits of the pixel array 200.

The pixel array 200 includes, for example, a plurality of pixels 201 arranged in a two-dimensional matrix, a plurality of drive lines Vg1 to Vg5 extending in a row direction, and a plurality of signal lines Sig1 to Sig2 extending in a column direction, and a bias line Bs.

In FIG. 2, for the sake of explanation, the pixel array or circuit 200 includes pixels or pixel circuits 201 arranged in 4 rows × 4 columns. However, in practice, the pixel array 200 may include a greater number of pixels 201. In one example, the radiation detection panel 111 has dimensions of 17 inches and includes pixels 201 arranged in approximately 3000 rows and approximately 3000 columns. Each pixel 201 includes a conversion element or circuit and a switch element or circuit.

The pixel array 200 includes a plurality of conversion elements or circuits C11 to C44 and a plurality of switch elements or circuits S11 to S44. In the following description, the conversion elements C11 to C44 will be collectively referred to as conversion elements C. The description regarding a conversion element C applies to each of the conversion elements C11 to C44. Similarly, the switch elements S11 to S44, the drive lines Vg1 to Vg5, and the signal lines Sig1 to Sig2 are collectively referred to as switch elements S, drive lines Vg, and signal lines Sig, respectively.

The rows of the pixel array 200 are sequentially referred to as 1st to 4th rows from the top as viewed on the figure, and the columns of the pixel array 200 are sequentially referred to as 1st to 4th columns from the left as viewed on the figure. Each pixel 201 includes a combination of one conversion element C and one switch element S. For example, a pixel 201 located in the first row and the second column includes a combination of a conversion element C12 and a switch element S12.

In each pixel 201, the conversion element C converts incident radiation into an electric signal (for example, a charge) wherein the switch element S is connected between the conversion element C and the signal line Sig corresponding to this conversion element C. For example, the switch elements S11, S12, S21 and S22 are connected between the plurality of conversion elements C11, C12, C21 and C22 and the signal line Sig1.

When a switch element S turns on, a conversion element C and a signal line Sig are electrically connected, and an electric signal obtained by the conversion element C (for example, the charge accumulated in the conversion element C) is transferred to the signal line Sig.

Each conversion element C may be, for example, a metal-insulator-semiconductor (MIS)-type photodiode formed on an insulating substrate such as a glass substrate wherein the MIS-type photodiode may be made mainly of amorphous silicon. Alternatively, each conversion element C may be a PIN photodiode. Each conversion element C may be of a direct type that converts radiation directly into an electric charge, or may be of an indirect type that first converts radiation into light and then detects the light. In the case where the conversion elements C are of the indirect type, a scintillator may be shared by a plurality of pixels 201.

Each switch element S incudes, for example, a transistor such as a thin film transistor (TFT) having a control terminal (a gate) and two main terminals (a source and a drain). The conversion element C has two main electrodes. One main electrode of the conversion element C is connected to one of the two main terminals of the switch element S, and the other main electrode of the conversion element is connected to a bias power supply Vs via a common bias line Bs. The bias power supply Vs generates a bias voltage.

The control terminals of the switch elements S of the pixels 201 in the first row and even columns are connected to the drive line Vg1, and the control terminals of the switch elements S of the pixels 201 in the first row and odd columns are connected to the drive line Vg2. The control terminals of the switch elements S of the pixels 201 in the second row and even columns are connected to the drive line Vg2, and the control terminals of the switch elements S of the pixels 201 in the second row and odd columns are connected to the drive line Vg3. The above applies to the third and fourth rows.

One of the main terminals of the switch element S of the pixel 201 in the first column is connected to the conversion element C of the same pixel 201, and the other one of the main terminals is connected to the conversion element C of the pixel 201 in the second column. That is, the switch element S of the pixel 201 in the first column is connected to the signal line Sig via the switch element S of the pixel 201 in the second column.

One of the main terminals of the switch element S of the pixel 201 in the second column is connected to the conversion element C of the same pixel 201, and the other one of the main terminals is connected to the signal line Sig. That is, the switch element S of the pixel 201 in the second column is connected between the conversion element C of the same pixel and the signal line Sig.

The above applies to the third and fourth columns.

For example, the switch element S12 is connected between the conversion element C12 and the signal line Sig1. Switch elements S11 and S12 are connected in series between the conversion element C11 and signal line Sig1. The switch element S11 is connected to the signal line Sig1 via the switch element S12. A switch element S22 is connected between the conversion element C22 and the signal line Sig1.

The conversion element C12 and the conversion element C22 are arranged along the direction in which the signal line Sig1 extends. The conversion element C11 and the conversion element C12 are arranged along the direction in which the drive line Vg1 extends.

In this connection configuration, the number of signal lines Sig is only half the number of columns of the pixel array 200. Furthermore, the number of drive lines Vg is larger by only one than the number of rows of the pixel array 200. Thus, compared to a configuration of a radiation detection panel in which one drive line is provided for each pixel row and one signal line is provided for each pixel column, it is possible to reduce the number of contacts between the pixel array 200 and the peripheral circuits (the drive circuit 210 and the readout circuit 220), that is, it is possible to reduce the total number of drive lines Vg and signal lines Sig. This makes it possible to simplify the configuration of the peripheral circuits.

Taking three conversion elements C11, C12, and C22, as examples, conditions for obtaining an electric conduction between these conversion elements and the signal line Sig1 are described. The conversion element C12 and the signal line Sig1 are electrically connected to each other when the switch element S12 connected to the drive line Vg1 is in the on-state, while they are electrically disconnected when the switch element S12 connected to the drive line Vg1 is in the off-state.

The conversion element C22 and the signal line Sig1 are electrically connected to each other when the switch element S22 connected to the drive line Vg2 is in the on-state, while they are electrically disconnected when the switch element S12 connected to the drive line Vg2 is in the off-state. The conversion element C11 and the signal line Sig1 are electrically connected to each other when the switch element S12 connected to the drive line Vg1 and the switch element S11 connected to the drive line Vg2 are both in the on-state, while they are electrically disconnected when at least one of the switch elements S12 and S11 is in the off-state.

The drive circuit 210 supplies a drive signal to the control terminal of the switch element S of each pixel 201 via the drive line Vg according to a control signal supplied from the control circuit 112. When the control signal is at a high level, it functions as an on-signal for turning on a switch element S. When the control signal is at a low level, it functions as an off-signal for turning off the switch element S.

The drive circuit 210 includes, for example, a shift register, which performs a shift operation according to a control signal (for example, a clock signal) supplied from the control circuit 112. A specific example of the operation of the drive circuit 210 will be described later.

The readout circuit 220 amplifies and reads out an electric signal that is output by the conversion element C and appears on the signal line Sig. The readout circuit 220 includes one amplifier circuit 221 for each signal line Sig. In the example shown in FIG. 2, the pixel array 200 has two signal lines Sig, and thus the readout circuit 220 includes two amplifier circuits 221. Each amplifier circuit 221 includes, for example, an integral amplifier 222, a variable amplifier 223, a switch element 224, a capacitor 225 and a buffer circuit 226.

The switch element 224 and the capacitor 225 form a sample-and-hold circuit. The integral amplifier 222 includes, for example, an operational amplifier, an integral capacitor and a reset switch connected in parallel between an inverting input terminal and an output terminal of the operational amplifier. A reference voltage is supplied from a reference voltage source Vref to a non-inverting input terminal of the operational amplifier. When the reset switch turns on in response to a control signal RC (a reset pulse) supplied from the control circuit 112, the integral capacitor is reset and the potential of the signal line Sig is reset to a reference potential.

The variable amplifier 223 amplifies the signal from the integral amplifier 222 with a set gain.

The sample-and-hold circuit samples and holds the signal from the variable amplifier 223. Turning-on/off of the switch element 224 in the sample-and-hold circuit is controlled by a control signal SH supplied from the control circuit 112. The buffer circuit 226 buffers (by impedance conversion) the signal from the sample-and-hold circuit and outputs it.

The readout circuit 220 also includes a multiplexer 227 configured to sequentially select and output, in a predetermined order, signals supplied from the plurality of amplifier circuits 221. The multiplexer 227 includes, for example, a shift register, which performs a shift operation according to a control signal (for example, a clock signal) supplied from the control circuit 112. As a result of the shift operation, one signal is selected from signals output by the plurality of amplifier circuits 221.

The buffer circuit 230 buffers (by impedance conversion) the signal output from the multiplexer 227 and outputs it. The AD converter 240 converts the analog signal output from buffer circuit 230 into a digital signal. The output signal provided by the AD converter 240, that is, the radiation image data, is sent to the computer 120.

The scanning direction switching unit 400 outputs a scanning direction switching signal DIR depending on whether signals are to be read out pixel by pixel or pixel addition is to be performed, as will be described in a further detail later.

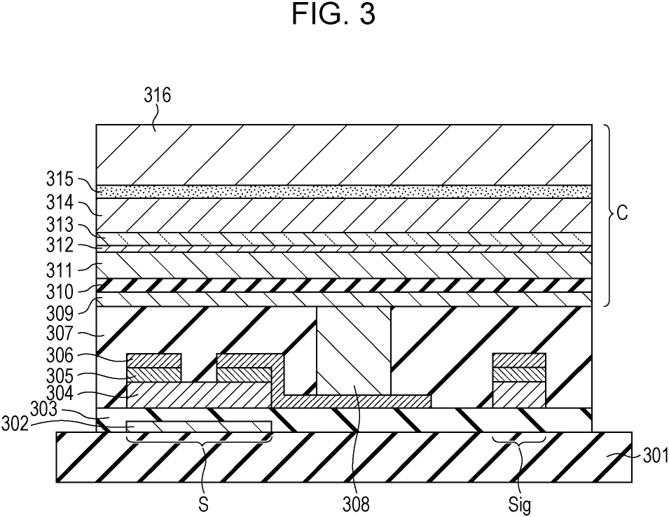

FIG. 3 schematically illustrates an example of a cross-sectional structure of one pixel 201. The pixel 201 is formed on an insulating substrate 301 such as a glass substrate. The pixel 201 includes a conductive layer 302, an insulating layer 303, a semiconductor layer 304, an impurity semiconductor layer 305, and a conductive layer 306, on the insulating substrate 301.

The conductive layer 302 constitutes a gate of a transistor (for example, a TFT) constituting the switch element S. The insulating layer 303 is provided so as to cover the conductive layer 302. The semiconductor layer 304 is disposed, via the insulating layer 303, on a part of the conductive layer 302 that constitutes the gate.

The impurity semiconductor layer 305 is provided on the semiconductor layer 304 so as to form two main terminals (a source and a drain) of the transistor constituting the switch element S.

The conductive layer 306 forms wiring patterns connected to the respective two main terminals (the source and the drain) of the transistor constituting the switch element S. A part of the conductive layer 306 constitutes the signal line Sig, and the other part constitutes a wiring pattern for connecting the conversion element C and the switch element S.

The pixel 201 further includes an interlayer insulating film 307 covering the insulating layer 303 and the conductive layer 306.

A contact plug 308 for connecting to the conductive layer 306 (the switch element S) is formed in the interlayer insulating film 307. The pixel 201 further includes a conductive layer 309, an insulating layer 310, a semiconductor layer 311, an impurity semiconductor layer 312, a conductive layer 313, a protective layer 314, an adhesive layer 315, and a scintillator layer 316, which are provided on the interlayer insulating film 307 in the order described above. The conversion element C of the indirect type is formed by these layers.

The conductive layer 309 and the conductive layer 313 respectively form a lower electrode and an upper electrode of a photoelectric conversion element of the conversion element C. The conductive layer 313 is made of, for example, a transparent material. The conductive layer 309, the insulating layer 310, the semiconductor layer 311, the impurity semiconductor layer 312, and the conductive layer 313 form an MIS sensor functioning as a photoelectric conversion element. The impurity semiconductor layer 312 is formed of, for example, an n-type impurity semiconductor layer. The scintillator layer 316 is made of, for example, a gadolinium-based material or a CsI (cesium iodide) material so as to be capable of converting radiation into light.

Instead of the above example of the configuration, the conversion element C may be configured as a conversion element of the direct type that directly converts incident radiation into an electric signal (a charge). A direct type conversion element C is made of, for example, main materials such as amorphous selenium, gallium arsenide, gallium phosphide, lead iodide, mercury iodide, CdTe, CdZnTe, and the like. The conversion element C is not limited to the MIS type, and may be, for example, a photodiode of a pn type, PIN type, or the like.

In the example shown in FIG. 3, each of the plurality of signal lines Sig overlaps a part of the conversion element C as seen in an orthographic projection to a plane in which the pixel array 200 is formed where drawing (that is, as seen in plan view). Such a configuration is advantageous in increasing the area of the conversion element C of each pixel 201, but this configuration is disadvantageous in that an increase occurs in the capacitive coupling between the signal line Sig and the conversion element C. When radiation is incident on the conversion element C, an electric charge is accumulated in the conversion element C. As a result, a change occurs in the potential of the conductive layer 309 (the lower electrode), which causes a change in the potential of the signal line Sig via the capacitive coupling between the signal line Sig and the conversion element C.

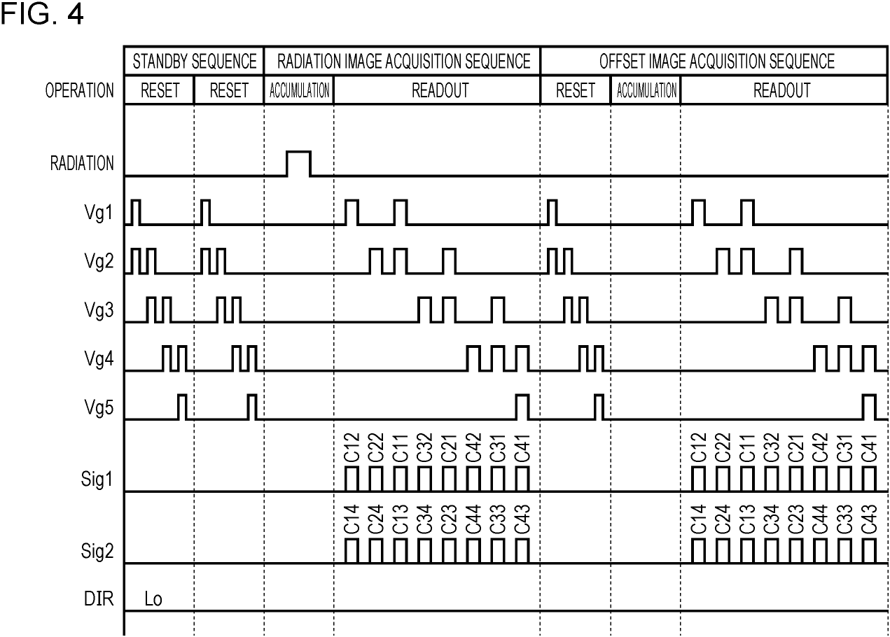

Referring to FIG. 4, an example of an operation of the radiation imaging system 100 is described below. The operation of the radiation imaging system 100 is controlled by the computer 120. The operation of the radiation imaging apparatus 110 is controlled by the control circuit 112 under the control of the computer 120. The operation shown in FIG. 4 is started, for example, in response to a command issued by a user of the radiation imaging system 100.

In FIG. 4, “OPERATION” indicates the operation of the radiation imaging system 100. The operation of the radiation imaging system 100 includes a standby sequence, a radiation image acquisition sequence, and an offset image acquisition sequence. The standby sequence is a sequence of operations performed when standing by for the start of irradiation of radiation.

The radiation image acquisition sequence is a sequence of operations performed to acquire a radiation image. The offset image acquisition sequence is a sequence of operations performed to acquire an offset image. The offset image is an image formed by signals obtained from the respective pixels 201 when no radiation is incident on the radiation imaging apparatus 110.

In FIG. 4, “RADIATION” indicates the presence/ absence of irradiation of radiation. A low level indicates the absence of irradiation of radiation, and a high level indicates the presence of irradiation of radiation. In FIG. 4, “Vg1” to “Vg5” indicate levels of drive signals supplied to the respective drive lines Vg1 to Vg5 from the drive circuit 210. When a low-level drive signal (an off-signal) is supplied to a drive line Vg, a switch element S connected to this drive line Vg turns off, while when a high level-level drive signal (an on-signal) is supplied to a drive line Vg, a switch element S connected to this drive line Vg turns on.

In FIG. 4, “Sig1” and “Sig2” indicate whether or not signals are being read out via respective signal lines Sig1 and Sig2, and also indicate conversion elements C from which the signals are read out. A low level indicates that no signal is read, while a high level indicates that a signal is being read out. At each position at which “Sig1” or “Sig2” is at the high level, a reference symbol is described to indicate a conversion element C from which a signal is read out.

In the standby sequence, the radiation imaging apparatus 110 repeats a reset operation. The reset operation is an operation of resetting a dark charge accumulated in the conversion element C of each pixel 201. The dark charge is a charge that occurs although the conversion element C is not irradiated with radiation. In the reset operation, the conversion elements C of the pixels 201 are sequentially reset from the pixels 201 in the first row to the pixels 201 in the last row (the fourth row). This reset operation is referred to as one reset operation. This reset operation is performed repeatedly by the radiation imaging apparatus 110.

During the reset operation, the control circuit 112 supplies an active level reset pulse to the reset switch of the integral amplifier 222. As a result, the signal line Sig is reset to the reference potential. In one reset operation, the drive circuit 210 supplies on-signals to the drive lines Vg1 and Vg2 to reset the pixels 201 in the first row. As a result, the conversion element C11 and the signal line Sig1 are electrically connected to each other, and the conversion element C12 and the signal line Sig1 are electrically disconnected. The same applies to the conversion elements C13 and C14.

Subsequently, the drive circuit 210 supplies on-signals to the drive lines Vg2 and Vg3 to reset the pixels 201 in the second row. In a similar manner, the drive circuit 210 resets the pixels 201 up to the fourth row.

When the control circuit 112 recognizes that the emission of radiation from the radiation source 140 is to start, for example, based on a start notification supplied from the exposure control apparatus 130 via the computer 120, the sequence shifts from the standby sequence to the radiation image acquisition sequence. Alternatively, the radiation imaging apparatus 110 may have a detection circuit configured to detect a current flowing through the bias line Bs, the signal line Sig, or the like of the pixel array 200, and based on an output signal supplied from this detection circuit, the control circuit 112 may recognize the start of the emission of radiation from the radiation source 140.

The radiation image acquisition sequence includes an accumulation operation and a readout operation. In the accumulation operation, the drive circuit 210 supplies off-signals to the respective drive lines Vg1 to Vg5 over a predetermined period of time. As a result, electric charges corresponding to the radiation incident on the conversion elements C are accumulated in the conversion elements C. In the subsequent readout operation, the control circuit 112 reads out the charges (electrical signals) accumulated in the respective conversion elements C.

The readout operation is described in further detail below. The following description will focus on reading the charge via the signal line Sig1, but the charge is read out through the signal line Sig2 in a similar manner.

First, the drive circuit 210 supplies an on-signal only to the drive line Vg1. As a result, the switch element S12 turns on, and the conversion element C12 and the signal line Sig1 are electrically connected to each other and thus the charge obtained in the conversion element C12 is read out to the signal line Sig1. In this state, the off-signal is supplied to the drive line Vg2, and thus the switch element S11 remains in the off-state, which causes the conversion element C11 and the signal line Sig1 to be in the electrically disconnected state. Therefore, the charge obtained in the conversion element C11 is not read out to the signal line Sig1 at this time.

After the charge obtained in the conversion element C12 is read out, drive circuit 210 supplies an on-signal only to drive line Vg2. As a result, the switch element S22 turns on, and the conversion element C22 and the signal line Sig1 are electrically connected to each other and thus the charge obtained in the conversion element C22 is read out to the signal line Sig1. Since the switch element S11 also turns on, the conversion element C11 and the conversion element C12 are electrically connected to each other via the switch element S11. As a result, part of the charge obtained in the conversion element C11 is transferred to the conversion element C12.

In this state, the off-signal is supplied to the drive line Vg1, and thus the switch element S12 is in the off-state, and the conversion element C11 and the signal line Sig1 are in the electrically disconnected state. Therefore, the charge obtained in the conversion element C11 is not read out to the signal line Sig1 at this time.

After the charge obtained in the conversion element C22 is read out, the drive circuit 210 supplies on-signals to both the drive line Vg1 and the drive line Vg2. As a result, the switch element S11 and the switch element S12 turn on, and the conversion element C11 and the signal line Sig1 are electrically connected to each other and thus the charge obtained in the conversion element C11 is read out to the signal line Sig1. In this state, since the on-signal is supplied to the drive line Vg2, the switch element S22 also turns on, and the conversion element C22 and the signal line Sig1 are electrically connected to each other.

Since the conversion element C22 has already been read out, no charge is read out from the conversion element C22 to the signal line Sig1 at this time. After that, the drive circuit 210 similarly supplies an e on-signal or the off-signal to the drive line Vg until the charges obtained in all the conversion elements C are read out.

A general readout operation of drive circuit 210 is further described below. Let k denote the number of drive lines Vg. An i-th (1 ≤ i ≤ k) drive line Vg as counted from one side of the pixel array 200 is referred to as a drive line Vg(i).

First, the drive circuit 210 supplies an on-signal to the drive line Vg(1) and supplies off-signals to all drive lines other than this drive line Vg(1). Subsequently, the drive circuit 210 supplies an on-signal to the drive line Vg(i+1), and then supplies on-signals to the drive lines Vg(i) and Vg(i+1) sequentially for i = 1 to i = k -2.

In this iteration, when the drive circuit 210 supplies an on-signal to the drive line Vg(i+1), the drive circuit 210 supplies off-signals to the other drive lines. When the drive circuit 210 supplies an on-signal to the drive line Vg(i) and the drive line Vg(i+1), the drive circuit 210 supplies off-signals to the other drive lines. Finally, the drive circuit 210 supplies on-signals to the drive lines Vg(k-1) and Vg(k), and supplies off-signals to the other drive lines.

In the operation method described above, for example, after reading out the charge from the conversion element C22 and before supplying on-signals to the drive lines other than the drive lines Vg1 and Vg2, the drive circuit 210 supplies on-signals to the drive line Vg1 and the drive line Vg2. By this, the drive circuit 210 reads out the charge obtained in the conversion element C11 to the signal line Sig1.

In other words, the drive circuit 210 performs the readout operation such that the readout of the charges from the conversion elements C to the signal line Sig1 is completed for all the conversion elements C belonging to the first pixel row before the charges obtained in the conversion elements C belonging to the third pixel row are read out to the signal line Sig1.

In general, the drive circuit 210 completes the readout of the charges obtained in all the conversion elements C belonging to the pixel rows up to the i-th pixel row to the signal line Sig1 before reading out the charges obtained in the conversion elements C belonging to the (i+2)th pixel row to the signal line Sig1 (where 1 ≤ i ≤ total number of pixel rows). This reduces the difference in elapsed time from the time of reset between even and odd pixel columns. As a result, deterioration in image quality can be suppressed compared with the conventional technology.

Note that the charge from the conversion element C12 is read out via one switch element S12, whereas the charge from the conversion element C11 is read out via two switch elements S11 and S12. Therefore, the drive circuit 210 supplies on-signals to the drive line Vg1 and the drive line Vg2 to read out the charge from the conversion element C11 for a longer period than a period for which the on-signal is supplied to the drive line Vg1 to read out the charge from the conversion element C12.

Note that in FIG. 4, the drive lines Vg are scanned from Vg1 to Vg5 (in a forward direction) to read out the charges (the electrical signal) accumulated in the conversion elements C individually pixel by pixel. During this process, a scanning direction switching signal DIR at a low level is supplied to the drive circuit 210 from the scanning direction switching unit 400. Note that in a pixel addition driving mode, which will be described later, a scanning direction switching signal DIR at a high level is supplied to the drive circuit 210, and the scanning is performed in a reverse direction from Vg5 to Vg1.

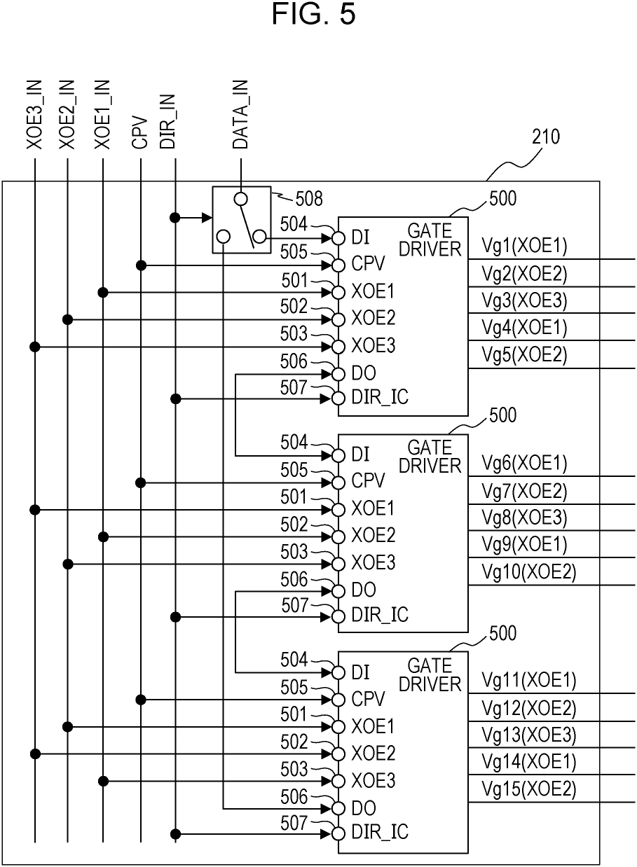

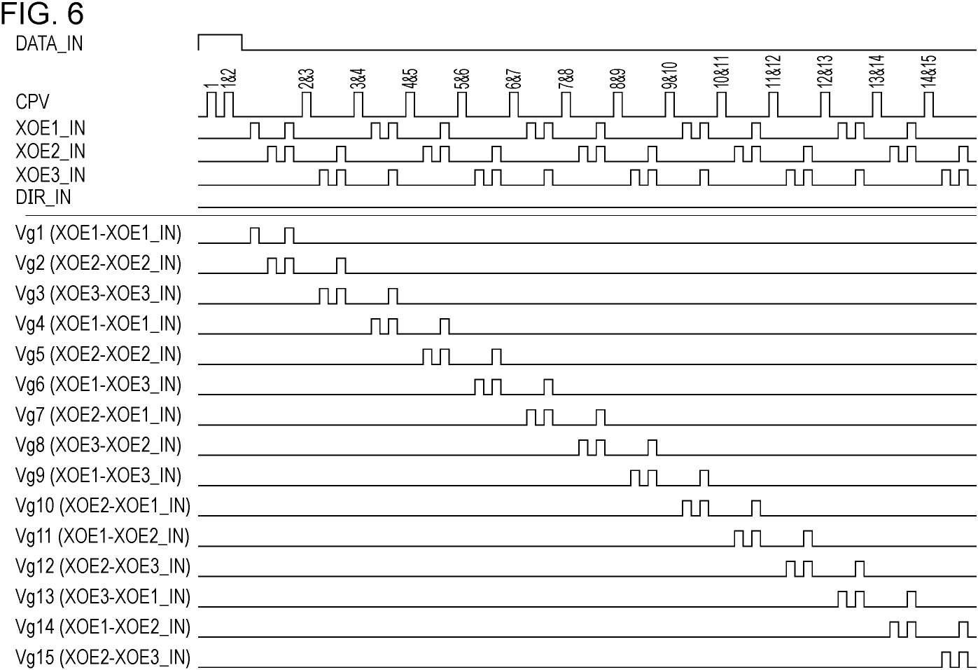

A specific example of the configuration of the drive circuit 210 and a specific example of a driving operation are described below with reference to FIG. 5 and FIG. 6. The drive circuit 210 includes a plurality of gate drivers 500. Each of the plurality of gate drivers 500 includes a data input terminal 504, a data output terminal 506, a shift clock terminal 505, three output enable terminals 501 to 503, and a scanning direction terminal 507.

The data input terminal 504 is for inputting a start signal for starting the operation of the shift register, and the data output terminal 506 is for outputting data to a next gate driver 500. When a clock signal is applied to the shift clock terminal 505, the signal input to the data input terminal 504 is sequentially shifted thereby sequentially scanning the drive lines.

The scanning direction terminal 507 is a terminal for switching the scanning direction of the gate drivers between the forward direction and the reverse direction. The data flowing direction between the data input terminal 504 and the data output terminal 506 is switched according to the signal input to the scanning direction terminal 507 between the direction from the data output terminal to the data input terminal and the direction from the data input terminal to the data output terminal. A switch 508 is switched by the scanning direction switching signal DIR between a state in which a DATA_IN signal is input to the data input terminal 504 and a state in which the DATA_IN signal is input to the data output terminal 506.

To allow the gate drivers to be also usable in a liquid crystal television using three colors of RGB, there are three output enable terminals 501 to 503. The gate drivers may be configured to have two output enable terminals instead of three output enable terminals. In such a case, the on-state and the off-state can be switched between the drive lines in even-numbered rows and the drive lines in odd-numbered rows. Control signals XOE1_IN, XOE2_IN, and XOE3_IN are supplied from the control circuit 112 to the output enable terminals 501, 502, and 503 of the respective gate drivers 500.

Each gate driver 500 in FIG. 5 has 5ch terminals for supplying signals to the drive lines Vg1 to Vg5, and the output enable terminals 501 to 503 correspond the drive lines Vg in a 3ch-periodic manner. More specifically, the output enable terminal 501 (XOE1) corresponds to the drive lines Vg1 and Vg4, the output enable terminal 502 (XOE2) corresponds to the drive lines Vg2 and Vg5, and the output enable terminal 503 (XOE3) corresponds to the drive line Vg3.

In the case of the first gate driver at the first position as counted from the top in FIG. 5, the control signal XOE1_IN from the control circuit 112 is input to the output enable terminal 501 (XOE1), the control signal XOE2_IN is input to the output enable terminal 502 (XOE2), and the control signal XOE3_IN is input to the output enable terminal 503 (XOE3).

In the second gate driver at the second position as counted from the top in FIG. 5, the control signal XOE1_IN from the control circuit 112 is input to the output enable terminal 502 (XOE2), the control signal XOE2_IN is input to the output enable terminal 503 (XOE3), and the control signal XOE3_IN is input to the output enable terminal 501 (XOE1).

In a case where a plurality of gate drivers 500 are used, the connections of the output enable terminals 501 to 503 of the gate drivers at the first and second positions as counted from the top in FIG. 5 are changed such that continuity of control signals XOE1_IN to XOE3_IN is maintained across the gate drivers 500. The drive line Vg5 corresponds to the output enable terminal 502 (XOE2), while the drive line Vg6 corresponds to the output enable terminal 501 (XOE1).

However, when the gate drivers 500 are scanned, it is needed to serially output the control signals in the order of XOE1_IN, XOE2_IN, XOE3_IN, XOE1_IN,...., and so on, otherwise switching will be needed in the middle of the operation. In view of the above, in the gate driver at the second position as counted from the top in FIG. 5, the control signal XOE3_IN is connected to the output enable terminal 501 (XOE1).

Next, the drive operation is described referring to FIG. 6. Here, to output signals from pixels on a pixel-by-pixel basis, the DIR_IN signal is set to the low level, and scanning is performed in the forward direction. The DATA_IN signal is supplied from the control circuit 112 to the data input terminal 504 of the gate driver 500 at the first position as counted from the top in FIG. 5, and the shift clock signal CPV is input twice to the shift clock terminal 505. As a result of this operation, Vg1 and Vg2 are selected at the first gate driver 500.

In this state, the output enable signal XOE1_IN is input. As a result, the drive line Vg1 is brought into the on-state. Next, the output enable signal XOE2_IN is input. As a result, the drive line Vg2 is brought into the on-state. Furthermore, the output enable signals XOE1_IN and XOE2_IN are simultaneously turned on. As a result, the drive lines Vg1 and Vg2 are simultaneously brought into the on-state.

Next, when the shift clock signal CPV is input once, Vg2 and Vg3 are selected at the first gate driver 500. In this state, the output enable signal XOE3_IN is input. As a result, the drive line Vg3 is brought into the on-state. Next, the output enable signals XOE2_IN and XOE3_IN are simultaneously turned on. As a result, the drive lines Vg2 and Vg3 are simultaneously brought into the on-state.

By inputting the shift clock signal CPV once and inputting the output enable signals XOE1_IN to XOE3_IN in the above-described manner, the drive line in the n-th row is turned on, and the n-th and n-1th rows are turned on simultaneously, and thus the drive operation shown in FIG. 4 is achieved.

The radiation imaging apparatus 110 transmits the charges of the respective conversion elements C obtained in the radiation image acquisition sequence, as the digital signal, to the computer 120 via the multiplexer 227, the buffer circuit 230, and the AD converter 240. By combining data of the respective pixels 201, a radiation image is obtained.

Next, the offset image acquisition sequence is described. The radiation image acquisition sequence includes a reset operation, an accumulation operation, and a readout operation. First, the control circuit 112 performs the reset operation once in the same manner as the reset operation in the standby sequence. As a result, the pixel array 200 is brought into the same state as before the radiation image acquisition sequence is started.

After that, the control circuit 112 performs the accumulation operation and readout operation in the same manner as in the radiation image acquisition sequence thereby acquiring an offset image. The offset image is also transmitted from the radiation imaging apparatus 110 to the computer 120 as with the radiation image. The offset image is then subtracted from the radiation image. As a result, offset components due to dark charges that occur in the conversion elements C during irradiation of radiation are removed from the radiation image.

In the readout operation described above, there is a possibility that a change in the sensitivity of the pixel 201 occurs. For example, when an on-signal is supplied to the drive line Vg2, the switch elements S11 and S22 turn on. In this case, part of the charge obtained in the conversion element C11 is transferred to the conversion element C12, which causes a change in the potential of the signal line Sig1 via the source-drain capacitance of the switch element S12. As a result, the amount of signal read out via the signal line Sig1 becomes greater than the amount of signal obtained in the conversion element C22.

On the other hand, for example, the charge obtained in the conversion element C11 is transferred to the signal line Sig1 via the two switch elements S11 and S12. As a result, there is a possibility that part of the charge obtained in the conversion element C11 remains in the conversion element C11 without being transferred, which causes a reduction in the sensitivity of the pixel 201 including the conversion element C11.

To reduce such a change in the sensitivity of the pixels 201, the radiation imaging apparatus 110 may divide an image captured in a state in which the object exists by an image captured in a state in which no object exists thereby making a gain correction.

Alternatively, the radiation imaging apparatus 110 may determine in advance a sensitivity ratio between a sensitivity obtained when driving is performed in a state where only a drive line Vg in one row is turned on and a sensitivity obtained when driving is performed in a state where only drive lines Vg in two rows are turned on, and may correct pixel values using this sensitivity ratio. Still alternatively, the aperture ratio may be different between the conversion elements C of the pixels 201 in the odd-numbered columns and the conversion elements C of the pixels 201 in the even-numbered columns. Still alternatively, the on-resistance may be different between the switch elements S of the pixels 201 in the odd-numbered columns and the switch elements S of the pixels 201 in the even-numbered columns.

Depending on the position in the pixel array 200 where the readout circuit 220 is connected to the pixel array 200, the length of the signal line Sig in the pixel array 200 changes. Since the signal line Sig generates thermal noise depending on the wiring length, the shorter the signal line Sig, the lower the noise. Random noise in an area of interest may be reduced by shortening the length of the signal line Sig in the central portion of the pixel array 200 which may be an area of interest.

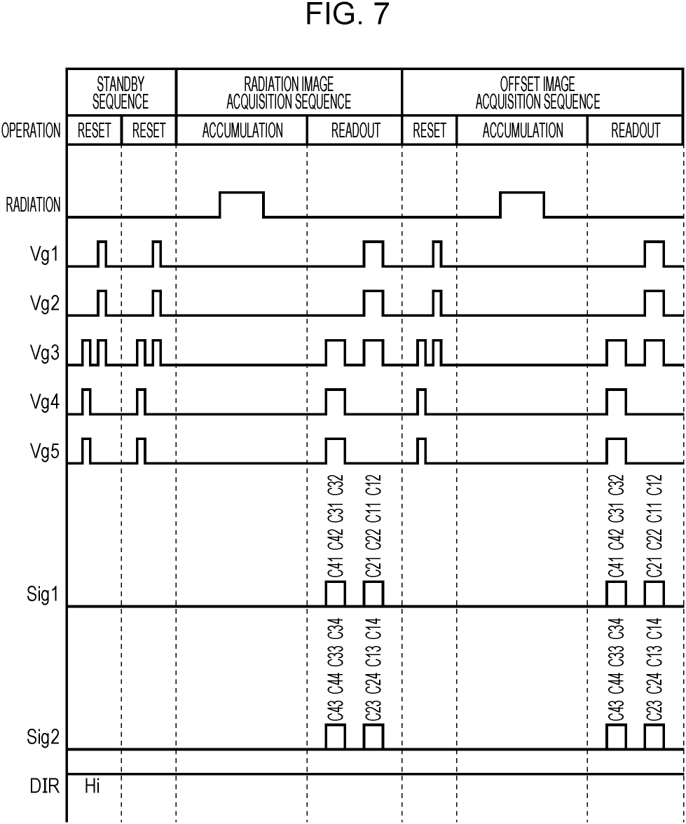

Next, an example of an operation of the radiation imaging system 100 is described with reference to FIG. 7. A duplicate description of similar parts of the operation to those described above with reference to FIG. 4 is omitted. FIG. 7 shows the operation performed when pixel addition is performed on 2 rows × 2 columns. In the case where readout is performed pixel by pixel, the scanning direction switching signal DIR is set to the low level by the scanning direction switching unit 400, and the scanning is performed in the forward direction from Vg1 to Vg5. In contrast, in the pixel addition driving mode, the scanning direction switching signal DIR is set to the high level, and the scanning is performed in the reverse direction from Vg5 to Vg1.

If the radiation imaging system 100 shown in FIG. 2 is driven in the forward scanning direction and the pixel addition is performed such that pixels in 2 rows × 2 are added together, then, when, for example, the drive lines Vg1 and Vg2 are turned on, then signals from conversion elements C11, C12, and C22 of three pixels are output to the signal line Sig1. On the other hand, when the drive lines Vg1, Vg2, and Vg3 are turned on, signals from conversion elements C11, C12, C21, C22, and C32 of five pixels are output to the signal line Sig1. As a result, the output signals do not correctly correspond to the layout of 2 rows × 2 columns, and a distortion occurs in pixel positions of the output signals.

On the other hand, in the case where the radiation imaging system 100 is driven in the reverse scanning direction and the pixel addition is performed such that pixels in 2 rows × 2 are added together, when the drive lines Vg5, Vg4, and Vg3 are turned on, signals from conversion elements C41, C42, C31, and C32 of four pixels in 2 rows × 2 columns are output to the signal line Sig1. In this case, since the drive line Vg3 is brought in the on-state, the switch element S21 turns on. However, the drive line Vg2 is in the off-state, and thus the switch element S22 is in the off-state. Therefore, the signal of the conversion element C21 is not output to the signal line Sig1.

Subsequently, when the drive lines Vg3, Vg2, and Vg1 are brought into the on-state, signals from the conversion elements C21, C22, C11, and C12 of four pixels in 2 rows × 2 columns are output. In this case, the drive line Vg3 is bought into the on-state and thus the switch element S32 is turned on, but the signal from the conversion element C32 has already been read out in the previous operation, and no signal remains in the conversion element C32. As a result, signals of 2 rows × 2 columns are collectively read out to one signal line.

In the case where the operation is performed in the above-described manner, signals of four pixels are added together when the signals are output to the readout circuit, and thus an image with a high S/N ratio can be obtained compared with a case where a radiation imaging panel is configured such that one signal line and one drive line are assigned to each pixel, and the radiation imaging panel is driven such that signals of 2 rows × 1 column are output to a signal line and then signals between columns are added in a readout circuit located following the radiation imaging panel.

Furthermore, it is possible to reduce the number of signal lines compared to the radiation imaging panel configured such that one signal line and one drive line are assigned to each pixel, and thus it is possible to increase the aperture ratio of the conversion element, which makes it possible to achieve an improved S/N ratio. This is particularly effective in a panel with a small pixel pitch which may cause signal lines to occupy a large area.

### Second Embodiment

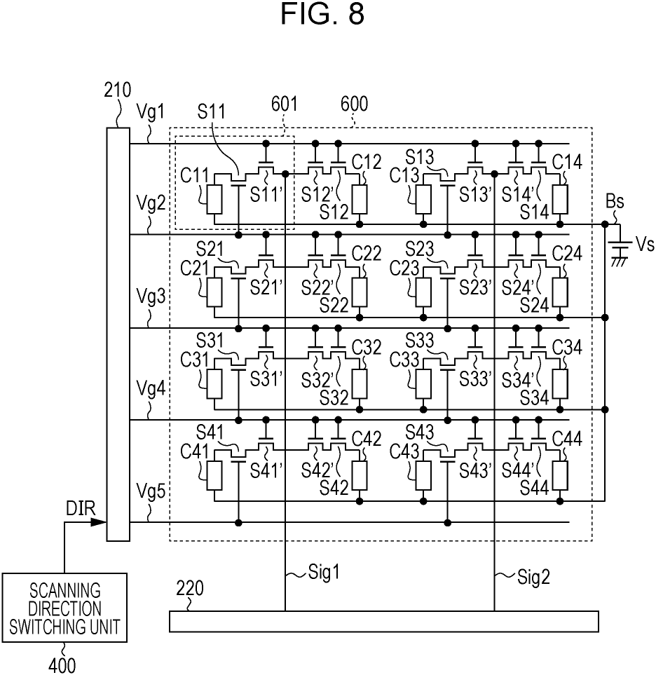

Next, a radiation detection panel according to second embodiment is described with reference to FIG. 8. The configuration shown in FIG. 8 is similar to that shown in FIG. 2 except that the pixel array 600 is provided instead of the pixel array 200.

The pixel array 600 includes, for example, a plurality of pixels 601 arranged in an array, a plurality of drive lines Vg1 to Vg5, a plurality of signal lines Sig1 to Sig2, and a bias line Bs. The pixel array 600 includes a plurality of conversion elements C11 to C44 and a plurality of switch elements S11 to S44 and S11′ to S44′.

In the following description, the conversion elements C11 to C44 will be collectively referred to as conversion elements C, and the switch elements S11 to S44 and S11′ to S44′ will be collectively referred to as switch elements S. Each pixel 601 includes a combination of one conversion element C and two switch elements S. For example, a pixel 601 in the first row and the second column is configured by a combination of a conversion element C12 and switch elements S12 and S12′.

The control terminals of the two switch elements S of a pixel 601 in the first row and an even-numbered column are connected to the drive line Vg1. The control terminal of one of the two switch elements S of a pixel 601 in the first row and an odd-numbered column is connected to the drive line Vg1, and the control terminal of the other one of the switch elements S is connected to the drive line Vg2. The above applies to the second to fourth rows. The conversion element C of each pixel 601 is connected to the signal line Sig via the two switch elements S which are connected in series and located in the same pixel 601.

For example, switch elements S11 and S11′ are connected in series between the conversion element C11 and the signal line Sig1. The switch element S11 is connected to the signal line Sig1 via the switch element S11′. The switch elements S12 and S12′ are connected in series between the conversion element C12 and the signal line Sig1. The switch elements S22 and S22′ are connected in series between conversion element C22 and signal line Sig1.

The conversion element C12 and the conversion element C22 are arranged along the direction in which the signal line Sig1 extends. The conversion element C11 and the conversion element C12 are arranged along the direction in which the drive line Vg1 extends.

Like the operation shown in FIG. 7, the pixel array 600 shown in FIG. 8 operates such that when the scanning direction switching signal DIR is set to the high level and the drive lines Vg5, Vg4, and Vg3 are turned on, signals from the conversion elements C41, C42, C31, and C32 of four pixels in 2 rows × 2 columns are output to the signal line Sig1. After that, the drive lines Vg3, Vg2, and Vg1 are turned on thereby outputting signals from the conversion elements C21, C22, C11, and C12 of four pixels in 2 rows × 2 columns. Thus a pixel addition operation is performed.

In the connection configuration described above, the number of signal lines Sig is only half the number of columns of the pixel array 600. Furthermore, the number of drive lines Vg is larger by only one than the number of rows of the pixel array 600. Thus, compared to a configuration of a radiation detection panel in which one drive line is provided for each pixel row and one signal line is provided for each pixel column, it is possible to reduce the number of contacts between the pixel array 600 and the peripheral circuits (the drive circuit 210 and the readout circuit 220), that is, it is possible to reduce the total number of drive lines Vg and signal lines Sig. This makes it possible to simplify the configuration of the peripheral circuits.

### Third Embodiment

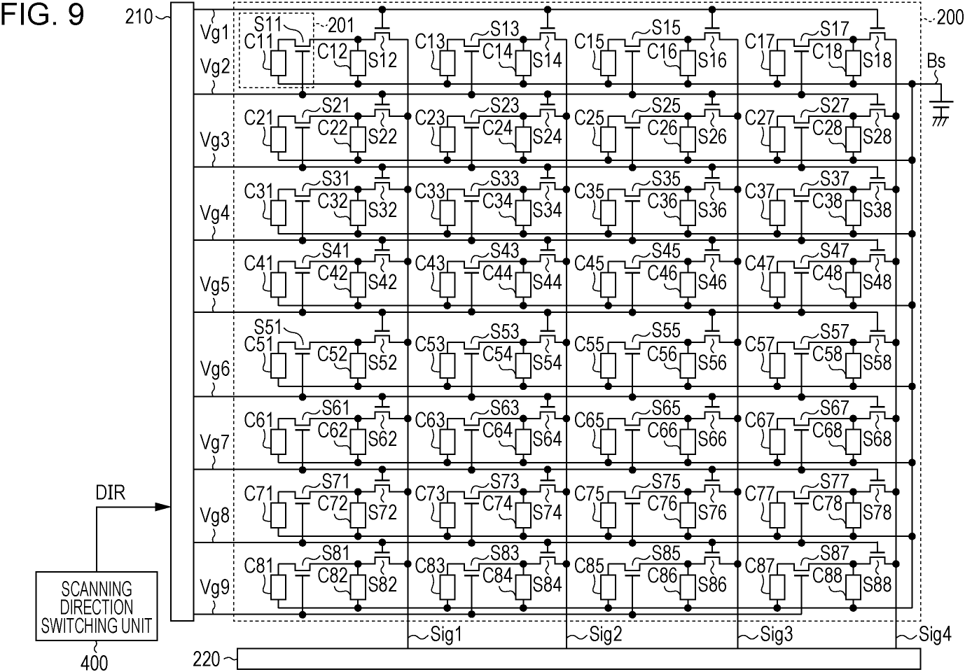

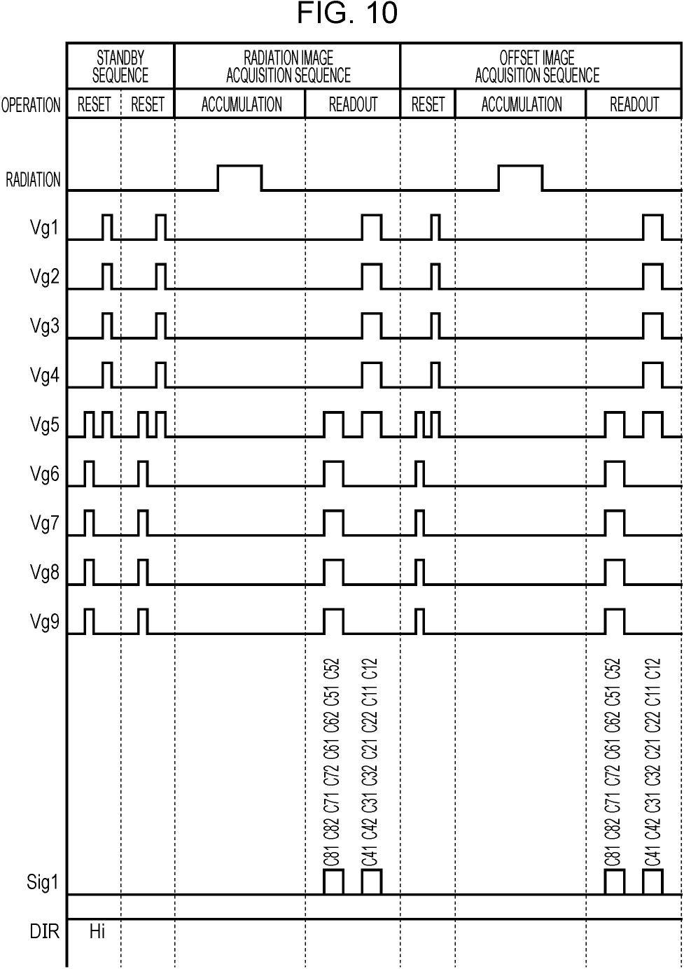

An example of a configuration of the radiation detection panel 111 and an example of an operation of the radiation imaging system 100 are described with reference to FIG. 9 and FIG. 10. A duplicated description of similar parts of the configuration or operation to those described above with reference to FIGS. 2, 4, or 7 is omitted.

In contrast to the radiation detection panel 111 shown in FIG. 2 having a pixel configuration of 4 rows × 4 columns, the radiation detection panel 111 shown in FIG. 9 has a pixel configuration of 8 rows × 8 columns.

In contrast to the operation described above with reference to FIG. 7 in which pixels in 2 rows × 2 columns are added together, the operation shown in FIG. 10 is performed such that pixel addition for 4 rows × 2 columns is performed inside the pixel array 200 and a column addition is performed by the readout circuit thereby finally achieving pixel addition for 4 rows × 4 columns.

When pixel addition for four rows is performed, the scanning direction switching signal DIR is set to the high level, and the scanning is performed in the reverse direction from Vg9 to Vg1. In this operation, when the drive lines Vg9, Vg8, Vg7, Vg6, and Vg5 are turned on, signals from the conversion elements C81, C82, C71, C72, C61, C62, C51, and C52 of eight pixels in 4 rows × 2 columns are output to the signal line Sig1.

In this case, as a result of turning on the drive line Vg5, the switch element S41 is turned on, but since the drive line Vg4 is in the off-state, and thus the switch element S42 is in the off-state. Therefore, the signal of the conversion element C41 is not output to the signal line Sig1.

Similarly, signals of conversion elements C83, C84, C73, C74, C63, C64, C53, and C54 of eight pixels in 4 rows × 2 columns are output to the signal line Sig2. The signal output to the signal line Sig1 and the signal output to the signal line Sig2 are added together by the readout circuit. As a result, pixels of 4 rows × 4 columns are added.

Subsequently, when the drive lines Vg5, Vg4, Vg3, Vg2, and Vg1 are turned on, the signals of conversion elements C41, C42, C31, C32, C21, C22, C11, and C12 of eight pixels in 4 rows × 2 columns are output to the signal line Sig1. At the same time, the signals of conversion elements C43, C44, C33, C34, C23, C24, C13, and C14 of eight pixels in 4 rows × 2 columns are output to the signal line Sig2. The signal output to the signal line Sig1 and the signal output to the signal line Sig2 are added together by the readout circuit. As a result, pixels of 4 rows × 4 columns are added.

As described above, when the scanning direction is switched from the scanning direction used in reading pixels on the pixel-by-pixel basis, the pixel addition is performed accurately.

### Fourth Embodiment

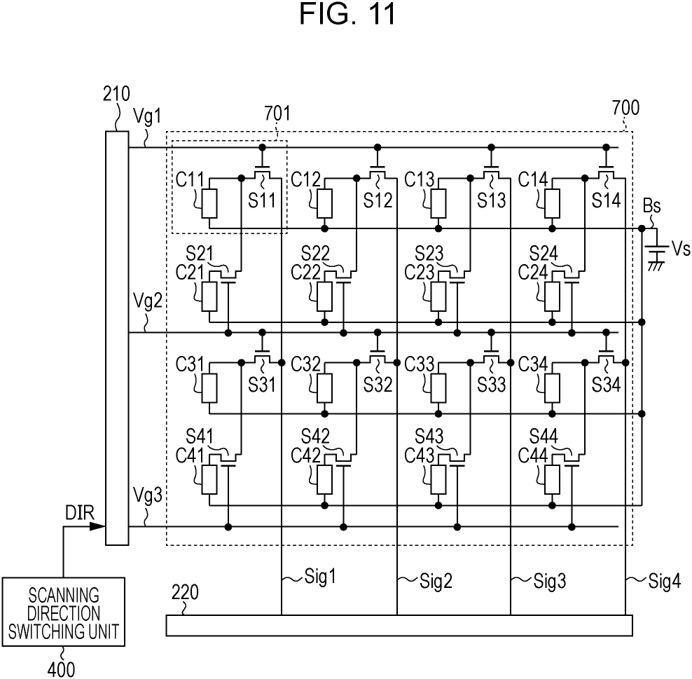

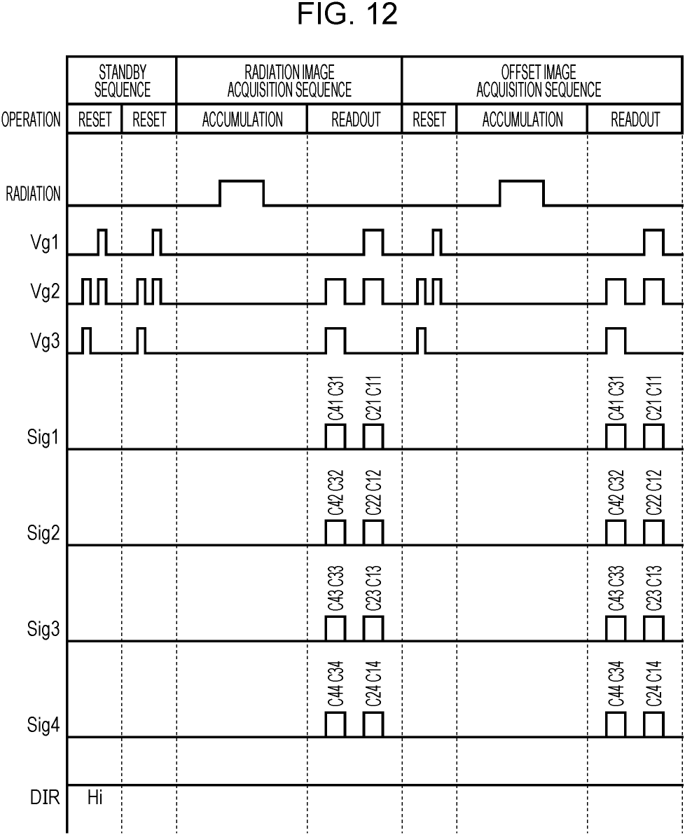

Referring to FIGS. 11 and 12, a fourth embodiment is described below in which the radiation imaging apparatus 110 is configured to include a pixel array 700 shown in FIG. 11 instead of the pixel array 200 shown in FIG. 2.

The pixel array 700 includes, for example, a plurality of pixels 701 arranged in an array, a plurality of drive lines Vg1 to Vg3, a plurality of signal lines Sig1 to Sig4, and a bias line Bs. The pixel array 700 includes a plurality of conversion elements C11 to C44 and a plurality of switch elements S11 to S44.

In the following description, the conversion elements C11 to C44 will be collectively referred to as conversion elements C, and the switch elements S11 to S44 will be collectively referred to as switch elements S. Each pixel 701 includes a combination of one conversion element C and two switch elements S. For example, a pixel 701 in the first row and the second column is configured by a combination of a conversion element C12 and a switch element S12.

The control terminal of the switch element S of each pixel 701 in the first row is connected to the drive line Vg1. The control terminal of the switch element S of each pixel 701 in the second row is connected to the drive line Vg2. The control terminal of the switch element S of each pixel 701 in the third row is connected to the drive line Vg2. The control terminal of the switch element S of each pixel 701 in the fourth row is connected to the drive line Vg3. The conversion element C of each pixel 701 in each odd-numbered row is connected to the signal line Sig via the switch element S included in the same pixel.

The conversion element C of each pixel 701 in each even-numbered row is connected to the signal line Sig via the switch element S included in the same pixel and the switch element S of another pixel adjacent to the same pixel in the column direction (in the direction in which the signal line Sig extends).

For example, the switch element S11 is connected between the conversion element C11 and the signal line Sig1. The switch elements S11 and S21 are connected in series between the conversion element C21 and signal line Sig1. The switch element S21 is connected to the signal line Sig1 via the switch element S11. The switch element S31 is connected between the conversion element C31 and the signal line Sig1. The conversion element C11, the conversion element C21, and the conversion element C31 are arranged along the direction in which the signal line Sig1 extends.

In the connection configuration described above, the number of drive lines Vg is equal to one plus only half the number of rows of the pixel array 700. The number of signal lines Sig is the same as the number of columns of the pixel array 700. Thus, compared to a configuration of a radiation detection panel in which one drive line is provided for each pixel row and one signal line is provided for each pixel column, it is possible to reduce the number of contacts between the pixel array 700 and the peripheral circuits (the drive circuit 210 and the readout circuit 220), that is, it is possible to reduce the total number of drive lines Vg and signal lines Sig. This makes it possible to simplify the configuration of the peripheral circuits.

Referring to FIG. 12, the readout operation in the pixel addition mode is described in detail below. The following description will focus on reading the charge via the signal line Sig1, but the operation is similar when the charge is read out via one of the signal lines Sig2 to Sig4.

First, the drive circuit 210 supplies on-signals to the drive lines Vg2 and Vg3. As a result, the switch elements S31 and S41 turn on, and thus the conversion element C41 and the conversion element C31 are electrically connected to the signal line Sig1. As a result, the charges obtained in the conversion elements C41 and C31 are read out to the signal line Sig1.

However, since the off-signal is supplied to the drive line Vg1, the switch element S11 is in the off-state and thus the conversion elements C11 and C21 are not electrically connected to the signal line Sig1. Therefore, at this time, the charges obtained in the conversion elements C11 and C21 are not read out to the signal line Sig1. Thus, the charges obtained in the conversion elements C32 and C42 are read out to the signal line Sig2. After the AD conversion is performed, the signal output via the signal line Sig1 and the signal output via the signal line Sig2 are added together thereby achieving the addition of pixels of 2 rows × 2 columns.

After the charges obtained in the conversion element C41 and the conversion element C31 are read out, the drive circuit 210 supplies on-signals to the drive lines Vg1 and Vg2. As a result, the switch element S11 and the switch element S21 turn on, and the conversion element C11 and the conversion element C21 are electrically connected to the signal line Sig1 and thus the charges obtained in the conversion element C11 and the conversion element C21 are read out to the signal line Sig1.

Since the switch element S31 also turns on, the conversion element C31 is electrically connected to the signal line Sig1. However, the charge obtained in the conversion element C31 has already been read out, and thus no charge is output to the signal line Sig1.

By performing the driving in the above-described manner, it becomes possible to achieve the accurate pixel addition.

### Fifth Embodiment

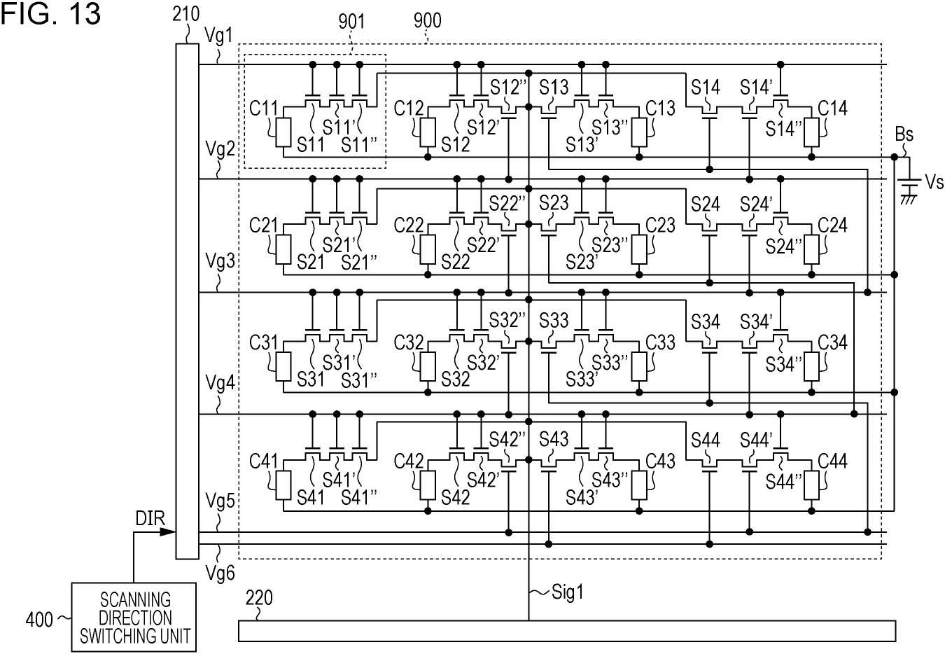

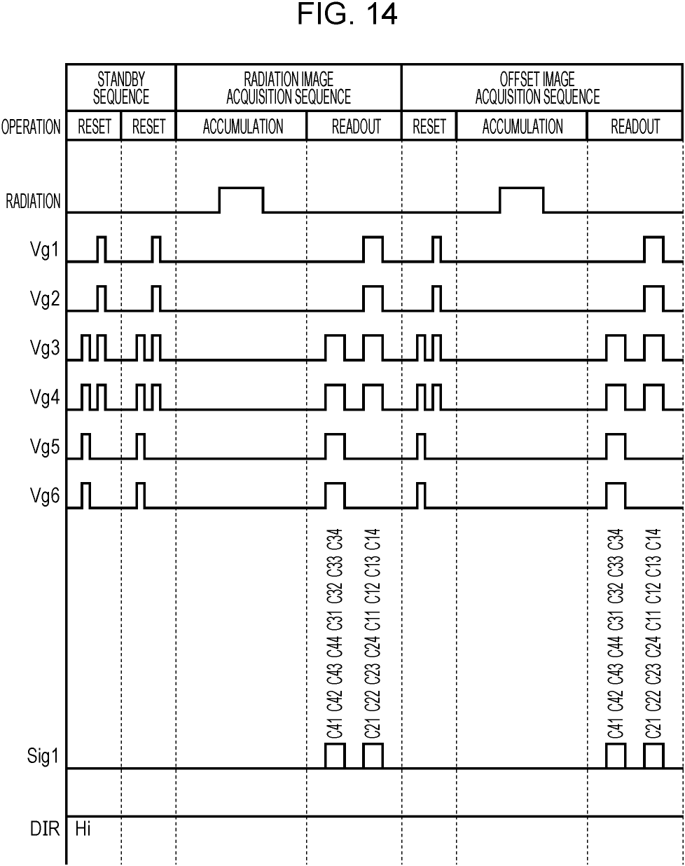

Referring to FIGS. 13 and 14, a fifth embodiment is described below in which the radiation imaging apparatus 110 is configured to include a pixel array 900 shown in FIG. 13 instead of the pixel array 200 shown in FIG. 2.

The pixel array 900 includes, for example, a plurality of pixels 901 arranged in an array, a plurality of drive lines Vg1 to Vg6, a signal line Sig1, and a bias line Bs. The pixel array 900 includes a plurality of conversion elements C11 to C44 and a plurality of switch elements S11 to S44, S11′ to S44′, and S11″ to S44″.

In the following description, the conversion elements C11 to C44 are collectively referred to as conversion elements C, and switch elements S11 to S44, S11′ to S44′, and S11″ to S44″ are collectively referred to as switch elements S. The signal line Sig1 will also be referred to as the signal line Sig. Each pixel 901 includes a combination of one conversion element C and three switch elements S. For example, a pixel 901 in the first row and the second column is configured by a combination of a conversion element C12 and switch elements S12, S12′, and S12″.

The control terminals of the three switch elements S of the pixel 901 in the first row and the first column are connected to the drive line Vg1. The control terminals of two of the three switch elements S of the pixels 901 in the first row and the second column are connected to the drive line Vg1, and the control terminal of the other one of the three switch elements S is connected to the drive line Vg2. The control terminals of two of the three switch elements S of the pixels 901 in the first row and the third column are connected to the drive line Vg1, and the control terminal of the other one of the three switch elements S is connected to the drive line Vg3.

The control terminal of one of the three switch elements S of the pixels 901 in the first row and the fourth column is connected to the drive line Vg1, the control terminal of another one of the three switch elements S is connected to the drive line Vg2, and the control terminal of the other one of the three switch elements S is connected to the drive line Vg3. The above applies to the second to fourth rows. In a case where the pixel array 900 includes more than five columns of pixels 901, the configuration of the first to fourth columns may be repeated. The conversion element C of each pixel 901 is connected to the signal line Sig via the three switch elements S connected in series.

For example, switch elements S11, S11′, and S11″ are connected in series between the conversion element C11 and the signal line Sig1. The switch elements S12, S12′, and S12″ are connected in series between the conversion element C12 and the signal line Sig1. The switch elements S12 and S12′ are connected to the signal line Sig1 via the switch element S12″. The switch elements S13, S13′, and S13″ are connected in series between the conversion element C13 and the signal line Sig1.

The switch elements S13″ and S13′ are connected to the signal line Sig1 via the switch element S13. The switch elements S14, S14′, and S14″ are connected in series between the conversion element C14 and the signal line Sig1. The switch element S14″ is connected to the signal line Sig1 via the switch elements S14 and S14′. The switch elements S21, S21′, and S21″ are connected in series between the conversion element C21 and the signal line Sig1.

The conversion element C11 and the conversion element C21 are arranged along the direction in which the signal line Sig1 extends. The conversion element C11, the conversion element C12, the conversion element C13, and the conversion element C14 are arranged along the direction in which the drive line Vg1 extends.

In the connection configuration described above, the number of signal lines Sig is only one-fourth the number of columns of the pixel array 900. Furthermore, the number of drive lines Vg is larger by only two than the number of rows of the pixel array 900.

Thus, compared to the configuration according to the first embodiment, it is possible to reduce the number of contacts between the pixel array 900 and the peripheral circuits (the drive circuit 210 and the readout circuit 220), that is, it is possible to reduce the total number of drive lines Vg and signal lines Sig. This makes it possible to further simplify the configuration of the peripheral circuits.

Referring to FIG. 14, the readout operation in the pixel addition mode in which pixels in 2 rows × 4 columns are added together is described in detail below.

First, the drive circuit 210 supplies on-signals to the drive lines Vg3 to Vg6. As a result, the switch elements S connected to the drive lines Vg3 to Vg6 turn on, and the conversion elements C31, C32, C33, C34, C41, C42, C43, and C44 are electrically connected to the signal line Sig1. As a result, the charges obtained in the conversion elements C31, C32, C33, C34, C41, C42, C43, and C44 are read out to the signal line Sig1.

In this state, since the off-signal is supplied to the drive line Vg2, the conversion elements C21, C22, C23, and C24 are electrically disconnected from the signal line Sig1. Therefore, at this time, the charges obtained in the conversion elements C21, C22, C23 and C24 are not read out to the signal line Sig1.

After the charges obtained in the conversion elements C31, C32, C33, C34, C41, C42, C43 and C44 are read out, the drive circuit 210 supplies on-signals to the drive lines Vg1 to Vg4. As a result, the switch elements S connected to the drive lines Vg1 to Vg4 turn on, and the conversion elements C11, C12, C13, C14, C21, C22, C23, and C24 are electrically connected to the signal line Sig1. As a result, the charges obtained in the conversion elements C11, C12, C13, C14, C21, C22, C23, and C24 are read out to the signal line Sig1.

At this time, the conversion elements C31 and C32 are electrically connected to the signal line Sig1, but the charges obtained in the conversion elements C31 and C32 have already been read out, and thus no charges are output from these conversion elements to the signal line Sig1. By performing the driving in the above-described manner, it becomes possible to achieve the accurate pixel addition.

### Other Embodiments

The present disclosure can also be realized by performing processing such that a program for realizing the functions described above is supplied to a system or an apparatus via a network or a storage medium, and the program is read out and executed by one or more processors in a computer of the system or the apparatus.

Examples usable as the storage medium include a flexible disk, an optical disc (such as a CD-ROM, a DVD-ROM, or the like), a magneto-optical disk, a magnetic tape, a non-volatile memory (such as a USB memory), a ROM, etc. The program for realizing the functions may be downloaded via a network and executed by a computer.

Note that the achieving of the functions of the above-described embodiments are not limited to the case where the program code is read and executed by the computer. Part or all of the process may be performed by an operating system or the like running on the computer in accordance with the program code. Such implementation of the functions also falls within the scope of the present disclosure.

Furthermore, the scope of the present disclosure also includes a case where a program code is loaded from a storage medium into a memory provided on a function extension board inserted in a computer or provided in a function extension unit connected to the computer. Part or all of the process may be performed by a CPU or the like disposed on the function extension card or the function extension unit in accordance with the loaded program code. Note that such implementation of the functions also falls within the scope of the present disclosure.

It should be noted that the above-described embodiments of the present disclosure are merely specific examples of carrying out the present disclosure, and the technical scope of the present disclosure is not to be construed to be limited by these embodiments. That is, the present disclosure can be implemented in various forms without departing from the technical idea or main features thereof.

As described above, according to the embodiments of the present disclosure, it is possible to achieve the accurate pixel addition while reducing the number of contacts between the pixel array and the peripheral circuit.

Embodiment(s) of the disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2021-174756 filed Oct. 26, 2021, which is hereby incorporated by reference herein in its entirety.

What is claimed is:

1. A radiation imaging apparatus comprising:
a plurality of conversion elements arranged in a two-dimensional matrix and each configured to convert radiation into an electric signal, the plurality of conversion elements including a first conversion element, a second conversion element adjacent in a row direction to the first conversion element, a third conversion element adjacent in a column direction to the first conversion element, a fourth conversion element adjacent in the column direction to the second conversion element and adjacent in the row direction to the third conversion element;
a signal line for reading electric signals obtained by the plurality of conversion elements, the signal line being connected to the second conversion element and the fourth conversion element, to the first conversion element via the second conversion element, and to the third conversion element via the fourth conversion element;
a plurality of switch elements including a first switch element connected between the first conversion element and the second conversion element, a second switch element connected between the second conversion element and the signal line, a third switch element connected between the third conversion element and the fourth conversion element, a fourth switch element connected between the fourth conversion element and the signal line;
a plurality of drive lines including a first drive line connected to a control terminal of the first switch element, a second drive line connected to a control terminal of the second switch element and a control terminal of the third switch element, and a third drive line connected to a control terminal of the fourth switch element; and
a drive circuit configured to supply, to each of the plurality of drive lines, an on-signal for turning on a switch element or an off-signal for turning off a switch element,
wherein the drive circuit reads out signals respectively from the first conversion element and the second conversion element by simultaneously supplying the on-signal to the first drive line and the second drive line, and then reads out signals respectively from the third conversion element and the fourth conversion element by simultaneously supplying the on-signal to the second drive line and the third drive line.

2. The radiation imaging apparatus according to claim 1, wherein the drive circuit switches a scanning direction between a case where signals from the plurality of conversion elements are read out individually and a case where signals from two or more conversion elements of the plurality of conversion elements are added and read out.

3. The radiation imaging apparatus according to claim 2, wherein the drive circuit switches a scanning direction between a case where signals from the first conversion element, the second conversion element, the third conversion element, and the fourth conversion element are read out individually and a case where signals from the first conversion element and the second conversion element are added and read out and signal from the third conversion element and the fourth conversion element are added and read out.

4. The radiation imaging apparatus according to claim 1, wherein the first conversion element and the second conversion element are provided along a direction in which the first drive line extends.

5. The radiation imaging apparatus according to claim 1, wherein the first conversion element and the third conversion element are provided along a direction in which the signal line extends.

6. The radiation imaging apparatus according to claim 1, wherein among the plurality of conversion elements, aperture ratios are different between conversion elements provided in odd-numbered columns and conversion elements provided in even-numbered columns.

7. The radiation imaging apparatus according to claim 1, wherein among the plurality of conversion elements, on-resistances are different between conversion elements provided in odd-numbered columns and conversion elements provided in even-numbered columns.

8. A radiation imaging system comprising:
the radiation imaging apparatus according to claim 1; and
a radiation source configured to irradiate the radiation imaging apparatus with radiation.

9. A method of controlling a radiation imaging apparatus, the radiation imaging apparatus comprising
a plurality of conversion elements arranged in a two-dimensional matrix and each configured to convert radiation into an electric signal, the plurality of conversion elements including a first conversion element, a second conversion element adjacent in a row direction to the first conversion element, a third conversion element adjacent in a column direction to the first conversion element, a fourth conversion element adjacent in the column direction to the second conversion element and adjacent in the row direction to the third conversion element,
a signal line for reading electric signals obtained by the plurality of conversion elements, the signal line being connected to the second conversion element and the fourth conversion element, to the first conversion element via the second conversion element, and to the third conversion element via the fourth conversion element,
a plurality of switch elements including a first switch element connected between the first conversion element and the second conversion element, a second switch element connected between the second conversion element and the signal line, a third switch element connected between the third conversion element and the fourth conversion element, a fourth switch element connected between the fourth conversion element and the signal line,
a plurality of drive lines including a first drive line connected to a control terminal of the first switch element, a second drive line connected to a control terminal of the second switch element and a control terminal of the third switch element, and a third drive line connected to a control terminal of the fourth switch element, and
a drive circuit configured to supply, to each of the plurality of drive lines, an on-signal for turning on a switch element or an off-signal for turning off a switch element,
the method comprising:
performing a first readout process to read signals from the first conversion element and the second conversion element by simultaneously supplying the on-signal to the first drive line and the second drive line; and
performing, following the first readout process, a second readout process to read signals from the third conversion element and the fourth conversion element by simultaneously supplying the on-signal to the second drive line and the third drive line.

10. A non-transitory storage medium containing instructions that, when executed by a processor, cause the processor to execute the control method according to claim 9.
